(19) United States
(12) Patent Application Publication
(10) Pub. No.: US 2012/0321846 A1
(43) Pub. Date: Dec. 20, 2012

(54) TRANSPARENT ELECTROCONDUCTIVE FILM AND ORGANIC ELECTROLUMINESCENT DEVICE

(75) Inventors: Kazuaki NAKAMURA, Tokyo (JP); Takayuki SUZUKI, Tokyo (JP)

(73) Assignee: KONICA MINOLTA HOLDINGS, INC., Tokyo (JP)

(21) Appl. No.: 13/524,546

(22) Filed: Jun. 15, 2012

(30) Foreign Application Priority Data
Jun. 17, 2011 (JP) 2011-134872

(51) Int. Cl. H01B 1/12; B32B 3/10; B32B 27/18

(52) U.S. Cl. 428/137; 252/500; 428/419; 428/203; 428/209

(57) ABSTRACT

Provided is a transparent electroconductive film. The film includes a transparent electroconductive layer. The layer contains an electroconductive polymer and a self-dispersing polymer dispersible into aqueous solvent. The self-dispersing polymer has a dissociable group, and has a glass transition point of 25° C. or higher and 80° C. or lower.

### CROSS-REFERENCE TO RELATED APPLICATION

The present U.S. patent application claims a priority under the Paris Convention of Japanese patent application No. 2011-134872 filed on Jun. 17, 2011, which shall be a basis of correction of an incorrect translation, and is incorporated by reference herein.

### BACKGROUND OF THE INVENTION

1. Technical Field

The present invention relates to a transparent electroconductive film successfully applicable to various fields including liquid crystal display device, organic electroluminescent device, inorganic electroluminescent device, solar battery, electromagnetic shield, electronic paper, touchscreen and so forth, and an organic electroluminescent device (also referred to as “organic EL device”, hereinafter) having the transparent electroconductive film.

2. Related Art

With the recent growing demand for thin TV set, display technologies of various styles, including those making use of liquid crystal, plasma, organic electroluminescence, field emission and so forth have been developed. For all of these displays of different styles, transparent electrode is an essential technology. Besides the TV sets, the transparent electrode is also indispensable for touchscreen, mobile phone, electronic paper, various types of solar batteries, and various types of electroluminescent/electrochromic device.

The conventional transparent electrode having been most widely used was an ITO transparent electrode which is composed of an indium tin composite oxide (ITO) film formed by deposition or sputtering on a transparent base such as those composed of glass, transparent plastic film or the like. The transparent electrode has, however, been desired to disuse indium, since it is a rare metal and the price of which has been soaring. There has been another growing demand of roll-to-roll production using a flexible base, aiming at production of larger screen and improvement in the productivity.

In recent years, in order to make the transparent electrode adoptable to such products which are required to have large area and low electrical resistivity, there has been developed a transparent electroconductive film having a patterned metal fine wire and a transparent electroconductive material typically composed of an electroconductive polymer film stacked thereon, so as to ensure desirable levels of in-plane uniformity of resistance and high electroconductivity (see JP-A-2005-302508 and JP-A-2009-87843, for example). The configuration, however, needs to smoothen irregularity of metal fine wire, causative of leakage of organoelectric devices, using a transparent electroconductive material composed of an electroconductive polymer or the like. It is, therefore, essential to thicken the electroconductive polymer film. The electroconductive polymer film, however, shows absorption in the visible light region, so that thickening thereof considerably degrades the transparency of the transparent electroconductive film.

Techniques capable of achieving both of electroconductivity and transparency have been disclosed as follows: a technique of stacking an electroconductive polymer on a metal fine wire structure (see JP-A-2009-4348, for example); a technique of applying, on an electroconductive fabric, an electroconductive polymer and a binder resin uniformly dispersible into an aqueous solvent (see JP-A-2010-244746, for example); and a technique of stacking an electroconductive polymer and a binder on an electroconductive layer (see JP-A-2011-96437, for example).

These techniques are, however, still insufficient to achieve desirable levels of sheet resistance and transmittance, and to achieve them at the same time. The technique disclosed in JP-A-2011-96437 needs high temperature and long time for drying so as to fully proceed the crosslinking reaction, and this means a large load of processes. Unreacted materials in the crosslinking reaction or eliminated products derived from the crosslinking reaction may adversely affect the transparent electrode and the organic EL device during storage, so that a desirable level of storability is not obtainable. It is still also anticipated that a desired level of surface smoothness of the transparent electroconductive film is not obtainable if a polymer having a low glass transition point is used for the transparent electrode, and that performances of the transparent electrode and the organic EL device after environmental test may degrade.

### SUMMARY OF THE INVENTION

The present invention was conceived after considering the subjects described in the above. The present invention is to provide a transparent electroconductive film excellent in the transparency, electroconductivity, and strength of film, and less likely to degrade the transparency, electroconductivity, and strength of film even under high-temperature, high-humidity environments. The present invention is also to provide an organic EL device using the transparent electroconductive film, excellent in emission uniformity, less causative of degradation in the emission uniformity even under high-temperature, high-humidity environments, and have a long service life of emission.

According to a first embodiment of the present invention, there is provided a transparent electroconductive film including a transparent electroconductive layer. The transparent electroconductive film contains an electroconductive polymer and a self-dispersing polymer dispersible into aqueous solvent. The self-dispersing polymer has a dissociable group, and has a glass transition point of 25° C. or higher and 80° C. or lower.

According to a second embodiment of the present invention, there is provided a transparent electroconductive film including a patterned metal-containing electroconductive layer, and a transparent electroconductive layer formed on the metal-containing electroconductive layer. The transparent electroconductive layer contains an electroconductive polymer and a self-dispersing polymer dispersible into aqueous solvent. The self-dispersing polymer has a dissociable group, and has a glass transition point of 25° C. or higher and 80° C. or lower.

### BRIEF DESCRIPTION OF THE DRAWINGS

The above and other objects, advantages and features of the present invention will become more fully understood from the detailed description given hereinbelow and the appended drawings which are given by way of illustration only, and thus are not intended as a definition of the limits of the present invention, and wherein:

FIG. 1A is a top view of an exemplary transparent electrode of the present invention;

FIG. 1B is a cross sectional view taken along line B-B in FIG. 1A;

FIG. 2A is a top view of an exemplary organic EL device of the present invention;

FIG. 2B is a cross sectional view taken along line B-B in FIG. 2A.

### DETAILED DESCRIPTION OF THE INVENTION

Aiming at attaining both of desirable levels of electroconductivity and transmissivity of the transparent electroconductive film at the same time, compositions composed of a water-dispersible electroconductive polymer such as 3,4-polyethylene dioxythiophene polystyrene sulfonate (PEDOT/PSS), and a binder resin, have been developed as a coating liquid for forming the transparent electroconductive film.

The binder resin having been investigated is a hydrophilic binder resin, from the viewpoint of compatibility with the water-dispersible electroconductive polymer. From another viewpoint of growing demand for flexibility, use of a resin film such as polyethylene terephthalate film as the transparent base has been investigated. Use of the resin film as the transparent base, however, raises a need of drying of the binder resin at a temperature lower than in the process of using a glass substrate, in order to avoid deformation of the base.

Hydroxy group-containing binder resin has been known to be compatible with PEDOT/PSS. The hydroxy group-containing binder resin causes dehydration between hydroxy groups under acidic conditions, and is thereby crosslinked between the polymer chains. Drying of the hydroxy group-containing binder resin at low temperatures, however, results in crosslinking failure, which allows the crosslinking reaction, and consequent generation of water, to proceed during the storage. Water remaining in the film has considerably degraded performance of the transparent electroconductive film and the device using the transparent electroconductive film. To solve this problem, it is necessary to reduce interaction between the principal skeleton of the binder and water, and to reduce the number of the hydroxyl groups in the binder resin or to totally exclude them. There has been another effort of using a surfactant so as to uniformly disperse the hydrophobic polymer into the aqueous solvent, only to result in adverse affect on performances of the obtained transparent electroconductive film and the device using the transparent electroconductive film.

The present inventors have extensively investigated into improvement in the nonconformities, and finally reached the present invention characterized by using a self-dispersing polymer as the binder resin, the self-dispersing polymer dispersible into aqueous solvent, having a dissociable group and having a glass transition point of 25° C. or higher and 80° C. or lower (dissociable group-containing, self-dispersing polymer).

In other words, the present inventors found out that the subjects of the present invention may be solved by using, as the binder resin to be mixed with the electroconductive polymer, a dissociable group-containing, self-dispersing polymer having a glass transition point of 25° C. or higher and 80° C. or lower, and dispersible into aqueous solvent, and finally reached the present invention.

The present embodiment of the invention is characterized by using a self-dispersing polymer as the binder resin. The self-dispersing polymer has a dissociable group and has a glass transition point of 25° C. or higher and 80° C. or lower, and dispersible into aqueous solvent, so as to suppress generation of water ascribable to the binder resin. By virtue of this configuration, the present embodiment successfully provides a highly stable transparent electroconductive film excellent in all of electroconductivity, transparency and film strength, even after environmental tests under high-temperature, high-humidity environments, and a long-life organic EL device using the transparent electroconductive film.

Embodiments for implementing the present embodiment will be explained below.

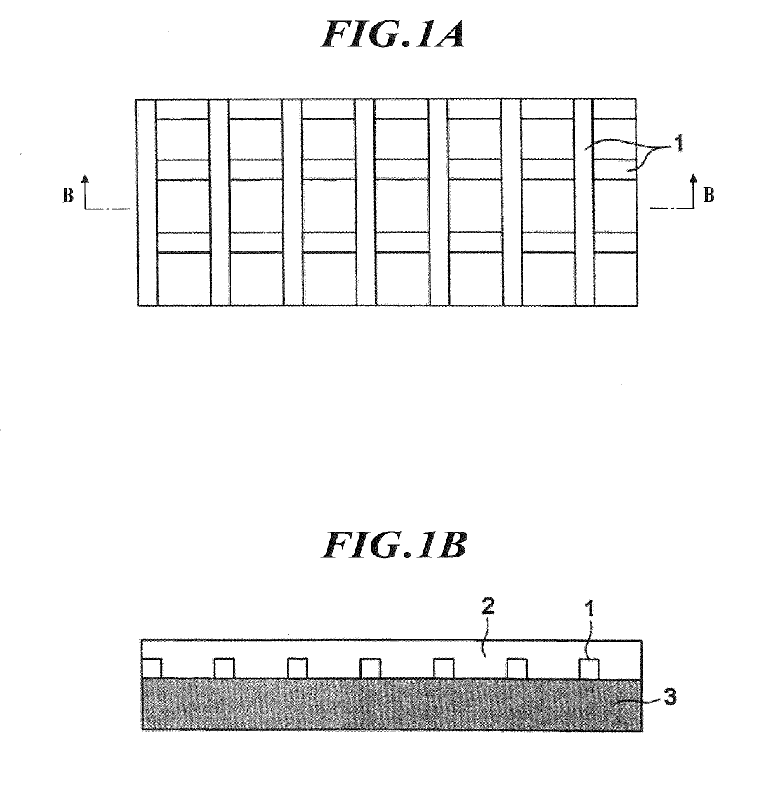

FIG. 1A is a top view illustrating an exemplary transparent electroconductive film of the present embodiment, and FIG. 1B is a cross sectional view taken along line B-B in FIG. 1A.

In FIG. 1, reference numeral 1 denotes a first electroconductive layer (metal-containing electroconductive layer), reference numeral 2 denotes a second electroconductive layer (transparent electroconductive layer), and reference numeral 3 denotes a transparent base. The first electroconductive layer 1 is composed of a patterned metal material. The second electroconductive layer 2 contains an electroconductive polymer and a dissociable group-containing, self-dispersing polymer dispersible in aqueous solvent. An essential feature of the present embodiment resides in that the second electroconductive layer 2 contains a dissociable group-containing, self-dispersing polymer dispersible in aqueous solvent.

### [Dissociable Group-Containing, Self-Dispersing Polymer]

The present embodiment relates to a transparent electroconductive film which includes a transparent base, and a transparent electroconductive layer containing an electroconductive polymer and a binder resin, wherein the binder resin has a glass transition point of 25° C. or higher and 80° C. or lower, and is dispersible into aqueous solvent. The binder polymer is the dissociable group-containing, self-dispersing polymer.

The dissociable group-containing, self-dispersing polymer dispersible into aqueous solvent, in the context of the present embodiment, contains none of surfactant and emulsifier capable of assisting micelle formation, but is dispersible alone by itself into aqueous solvent. “Dispersible into aqueous solvent” in the context of the present embodiment means that colloidal particle composed of the binder resin are dispersed in the aqueous solvent without causing coagulation. Size of colloidal particle is generally 0.001 to 1 (1 to 1000 nm) or around. The size of colloidal particle is preferably 3 to 500 nm, more preferably 5 to 300 nm, and still more preferably 10 to 100 nm. The size of colloidal particle is measurable by using a light scattering photometer.

The aqueous solvent means not only pure water (including distilled water and deionized water), but also aqueous solution containing acid, alkali, salt or the like; water-containing organic solvent; and still also hydrophilic organic solvent. The aqueous solvent is exemplified by pure water (including distilled water and deionized water); alcoholic solvent such as methanol and ethanol; and mixed solvent of water and alcohol.

The dissociable group-containing, self-dispersing polymer used in the present embodiment is preferably transparent.

The dissociable group-containing, self-dispersing polymer is not specifically limited, so long as it can form a film. Dispersion liquid of the polymer preferably contains none of surfactant (emulsifier) and plasticizer for controlling film forming temperature, while being not specifically limited so long as it does not bleed out to the surface of the transparent electroconductive film or does not adversely affect performances of the organic EL layers stacked thereon later.

pH of the dispersion liquid of the dissociable group-containing, self-dispersing polymer used for manufacturing of the transparent electroconductive film is preferably adjusted within the range not causative of separation from the electroconductive polymer solution to be mixed therewith, preferably in the range from 0.1 to 11.0, more preferably from 3.0 to 9.0, and still more preferably 4.0 to 7.0.

The glass transition point (Tg) of the dissociable group-containing, self-dispersing polymer used in the present embodiment is 25° C. or higher and 80° C. or lower, preferably 30 to 75° C., and more preferably 50 to 70° C. The glass transition point lower than 25° C. not only fails in obtaining surface smoothness of the transparent electroconductive film, but also degrades performances of the transparent electroconductive film and the organic EL device after environmental tests. The glass transition point is measurable using a differential scanning calorimeter (Model DSCO-7, from PerkinElmer Inc.), at a temperature elevation rate of 10° C./min., in compliance with JIS K 7121-1987.

The dissociable group contained in the dissociable group-containing, self-dispersing polymer is exemplified by anionic group (sulfonic acid and salt thereof, carboxylic acid and salt thereof, phosphoric acid and salt thereof, etc.), and cationic group (ammonium salt, etc.). Although not specifically limited, the dissociable group is preferably an anionic group, from the viewpoint of compatibility with the electroconductive polymer solution. The amount of dissociable group may be determined within the range capable of keeping the self-dispersing polymer dispersible into aqueous solvent, wherein the amount as small as possible will be better, from the viewpoint of process adequacy since the load of drying may be reduced. While counter species of the anionic group and cationic group are not specifically limited, they are preferably hydrophobic and exist in small amounts, when considering performances after being stacked thereon with the transparent electroconductive film and the organic EL device.

The principal skeleton of the dissociable group-containing, self-dispersing polymer is exemplified by polyethylene, polyethylene-polyvinyl alcohol (PVA), polyethylene-polyvinyl acetate, polyethylene-polyurethane, polybutadiene, polybutadiene-polystyrene, polyamide (nylon), polyvinylidene chloride, polyester, polyacrylate, polyacrylate-polyester, polyacrylate-polystyrene, polyvinyl acetate, polyurethane-polycarbonate, polyurethane-polyether, polyurethane-polyester, polyurethane-polyacrylate, silicone, silicone-polyurethane, silicone-polyacrylate, polyvinylidene fluoride-polyacrylate, and polyfluoroolefin-polyvinyl ether. Also copolymers, having other monomers introduced into the above-described skeletons, are adoptable. Among them, those having ester skeleton such as polyester resin and polyester-acryl resin, and those having ethylene skeleton such as polyethylene, are preferably used in the form of resin emulsion.

The dissociable group-containing, self-dispersing polymer are commercially available under the trade names of Polysol FP3000 (polyester resin, anionic, having acryl core and polyester shell, from Showa Denko K.K.), Vylonal MD1245 (polyester resin, anionic, from Toyobo Co. Ltd.), Vylonal MD1500 (polyester resin, anionic, from Toyobo Co. Ltd.), Vylonal MD2000 (polyester resin, anionic, from Toyobo Co. Ltd.), Plascoat RZ105 (polyester resin, anionic, from Goo Chemical Co. Ltd.), and Plascoat RZ570 (polyester resin, anionic, from Goo Chemical Co. Ltd.). The dissociable group-containing, self-dispersing polymer dispersible into aqueous solvent may be used alone, or in combination of two or more species.

The amount of use of the dissociable group-containing, self-dispersing polymer is preferably 50 to 1000% by mass of the electroconductive polymer, more preferably 100 to 900% by mass, and still more preferably 200 to 800% by mass.

### <Electroconductive Polymer>

The term “electroconductive” in the context of the present embodiment means a state of material allowing electric current to flow therethrough, and specifically means that sheet resistance of the material measured in compliance with JIS K 7194-1994, “Testing Method for Resistivity of Conductive Plastics with a Four-Point Probe Array”, is smaller than 1×10⁸Ω/□.

The electroconductive polymer used in the present embodiment has a π-conjugated electroconductive polymer and a polyanion. This sort of electroconductive polymer may readily be manufactured by allowing a later-described precursor monomer, composing the later-described π-conjugated electroconductive polymer, to oxidatively polymerize under the presence of an appropriate oxidizer, an oxidation catalyst, and a later-described polyanion.

### (π-Conjugated Electroconductive Polymer)

The π-conjugated electroconductive polymer adoptable to the present embodiment is not specifically limited, wherein examples of which include chain-like electroconductive polymers such as polythiophenes (including most simple polythiophene, the same will apply hereinafter), polypyrrols, polyindoles, polycarbazoles, polyanilines, polyacetylenes, polyfurans, polyparaphenylene vinylenes, polyazulenes, polyparaphenylenes, polyparaphenylene sulfides, polyisothianaphthenes, and polythiazyls. Among them, polythiophenes and polyanilines are preferable from the viewpoint of electroconductivity, transparency and stability. Polyethylene dioxythiophene is most preferable.

### (Precursor Monomer of π-Conjugated Electroconductive Polymer)

Precursor monomer used for forming the π-conjugated electroconductive polymer has a π-conjugated system in the molecule thereof, so that the polymer obtained by polymerizing the monomer while being assisted by an appropriate oxidizer retains the π-conjugated system in the principal chain thereof. Examples of the precursor monomer include pyrroles and derivatives thereof, thiophenes and derivatives thereof, and anilines and derivatives thereof.

Specific examples of the precursor monomer include pyrrole, 3-methylpyrrole, 3-ethylpyrrole, 3-n-propylpyrrole, 3-butylpyrrole, 3-octylpyrrole, 3-decylpyrrole, 3-dodecylpyrrole, 3,4-dimethylpyrrole, 3,4-dibutylpyrrole, 3-carboxylpyrrole, 3-methyl-4-carboxylpyrrole, 3-methyl-4-carboxyethylpyrrole, 3-methyl-4-carboxybutylpyrrole, 3-hydroxypyrrole, 3-methoxypyrrole, 3-ethoxypyrrole, 3-butoxypyrrole, 3-hexyloxypyrrole, 3-methyl-4-hexyloxypyrrole, thiophene, 3-methylthiophene, 3-ethylthiophene, 3-propylthiophene, 3-butylthiophene, 3-hexylthiophene, 3-heptylthiophene, 3-octylthiophene, 3-decylthiophene, 3-dodecylthiophene, 3-octadecylthiophene, 3-bromothiophene, 3-chlorothiophene, 3-iodothiophene, 3-cyanothiophene, 3-phenylthiophene, 3,4-dimethylthiophene, 3,4-dibutylthiophene, 3-hydroxythiophene, 3-methoxythiophene, 3-ethoxythiophene, 3-butoxythiophene, 3-hexyloxythiophene, 3-heptyloxythiophene, 3-octyloxythiophene, 3-decyloxythiophene, 3-dodecyloxythiophene, 3-octadecyloxythiophene, 3,4-dihydroxythiophene, 3,4-dimethoxythiophene, 3,4-diethoxythiophene, 3,4-dipropoxythiophene, 3,4-dibutoxythiophene, 3,4-dihexyloxythiophene, 3,4-diheptyloxythiophene, 3,4-dioctyloxythiophene, 3,4-didecyloxythiophene, 3,4-didodecyloxythiophene, 3,4-ethylene dioxythiophene, 3,4-propylene dioxythiophene, 3,4-butene dioxythiophene, 3-methyl-4-methoxythiophene, 3-methyl-4-ethoxythiophene, 3-carboxythiophene, 3-methyl-4-carboxythiophene, 3-methyl-4-carboxyethylthiophene, 3-methyl-4-carboxybutylthiophene, aniline, 2-methylaniline, 3-isobutylaniline, 2-aniline sulfonic acid, and 3-aniline sulfonic acid.

### (Polyanion)

Polyanion used for the electroconductive polymer in the present embodiment is exemplified by substituted or non-substituted polyalkylene, substituted or non-substituted polyalkenylene, substituted or non-substituted polyimide, substituted or non-substituted polyamide, substituted or non-substituted polyester and copolymers thereof, which are summarized by those composed of a constituent having an anionic group and a constituent having no anionic group.

The polyanion is a solubilizing polymer assisting solubilization of the π-conjugated electroconductive polymer into solvent. The anionic group of the polyanion also functions as a dopant (first dopant) for the π-conjugated electroconductive polymer, and improves the electroconductivity and heat resistance of the π-conjugated electroconductive polymer.

The anionic group of the polyanion may be any functional group, so long as they can oxidatively dope into the π-conjugated electroconductive polymer. Among others, monosubstituted sulfate ester group, monosubstituted phosphoric ester group, phosphoric acid group, carboxyl group, and sulfo group are preferable from the viewpoint of readiness of manufacturing and stability. Sulfo group, monosubstituted sulfuric ester group, and carboxyl group are more preferable, from the viewpoint of doping effect of the functional group into the π-conjugated electroconductive polymer.

Specific examples of the polyanion include polyvinyl sulfonic acid, polystyrenesulfonic acid, polyallylsulfonic acid, polyacrylic acid ethylsulfonic acid, polyacrylic acid butylsulfonic acid, poly-2-acrylamide-2-methylpropanesulfonic acid, polyisoprenesulfonic acid, polyvinylcarboxylic acid, polystyrenecarboxylic acid, polyallylcarboxylic acid, polyacrylcarboxylic acid, polymethacrylcarboxylic acid, poly-2-acrylamide-2-methylpropanecarboxylic acid, polyisoprenecarboxylic acid, and polyacrylic acid. The polyanion may be a homopolymer of these compound, or a copolymer composed of two or more species.

Also polyanion additionally containing F (fluorine atom) therein is adoptable. Specific examples of such polyanion include Nafion (from DuPont) having perfluorosulfonic acid group, and Flemion (from Asahi Glass Co. Ltd.) composed of perfluorovinyl ether having carboxylic acid groups.

For the case where the compounds having sulfonic acid groups, selected from the above-described compounds, are used, the electroconductive polymer-containing layer may be formed by coating and drying, and then may be dried under heating at 100 to 120° C. for 5 minutes or longer, before being irradiated with microwave. This process is preferable, since the crosslinking reaction may be promoted, and thereby durability against washing and solvent resistance of the coated film may be improved to a considerable degree.

Among them, polystyrenesulfonic acid, polyisoprenesulfonic acid, polyacrylic acid ethylsulfonic acid, and polyacrylic acid butylsulfonic acid are particularly preferable. These polyanions are excellent in the compatibility with the dissociable group-containing, self-dispersing polymer, and may further improve the electroconductivity of the resultant electroconductive polymer.

The degree of polymerization of the polyanion is preferably 10 to 100,000 in terms of the number of monomer units, and more preferably 50 to 10,000 from the viewpoint of solubility into solvent and electroconductivity.

Examples of methods of manufacturing of the polyanion include a method of directly introducing anionic groups with the aid of an acid into a polymer having no anionic group, a method of converting a polymer having no anionic group into a sulfonic acid using a sulfonating agent, and a method based on polymerization of an anionic group-containing polymerizable monomer.

The method based on polymerization of an anionic group-containing polymerizable monomer is exemplified by a method of allowing, in a solvent, an anionic group-containing polymerizable monomer to oxidatively polymerize or radically polymerize, under the presence of an oxidizer and/or polymerization catalyst. More specifically, a predetermined amount of anionic group-containing polymerizable monomer is dissolved into a solvent, the mixture is kept at a constant temperature, added with a solution prepared by preliminarily dissolving a predetermined amount of oxidizer and/or polymerization catalyst into a solvent, and the mixture is allowed to react for a predetermined period. Concentration of the polymer obtained by the reaction is adjusted to a certain level using a solvent. In this method of manufacturing, the anionic group-containing polymerizable monomer may be co-polymerized with a polymerizable monomer having no anionic group.

The oxidizer, oxidizing catalyst, and solvent used for polymerization of the anionic group-containing polymerizable monomer are similar to those used for polymerization of the precursor monomer for forming the π-conjugated electroconductive polymer.

If the thus-obtained polymer is a polyanionic salt, the polymer is preferably converted into polyanionic acid. Methods of conversion into polyanionic acid include ion exchange using an ion exchange resin, dialysis, and ultrafiltration. Considering readiness of implementation, ultrafiltration is preferable.

Ratio by mass of the π-conjugated electroconductive polymer and the polyanion contained in the electroconductive polymer, that is (π-conjugated electroconductive polymer):(polyanion), is preferably 1:1 to 1:20, and more preferably 1:2 to 1:10 from the viewpoint of electroconductivity and dispersibility.

The oxidizer, used for obtaining the electroconductive polymer according to the present embodiment by oxidatively polymerizing the precursor monomer for forming the π-conjugated electroconductive polymer under the presence of the polyanion, is any of the oxidizers suitable for oxidative polymerization of pyrrole described in J. Am. Chem. Soc., Vol. 85, p. 454 (1963), for example. For practical reasons, it is preferable to use inexpensive and readily handlable oxidizer such as iron (III) salt represented by FeCl₃ and Fe(ClO₄)₃, iron (III) salt of organic acid, hydrogen peroxide, potassium dichromate, alkali persulfate (potassium persulfate, sodium persulfate, for example), ammonium, alkali perborate, potassium permanganate, and copper salt represented by copper tetrafluoroborate. In addition, air and oxygen may optionally be used as the oxidizer, under the presence of catalytic amount of metal ion such as iron, cobalt, nickel, molybdenum and vanadium ions. Use of persulfate, and iron (III) salt of organic acid is of great practical advantage, by virtue of their non-corrosive natures.

Examples of the iron (III) salt of organic acid include iron (III) salts of C₁₋₂₀ alkanol half ester of sulfuric acid such as lauryl sulfate; C₁₋₂₀ alkylsulfonic acid such as methane- or dodecanesulfonic acid; aliphatic C₁₋₂₀ carboxylic acid such as 2-ethylhexylcarboxylic acid; aliphatic perfluorocarboxylic acid such as trifluoroacetic acid and perfluorooctanoic acid; aliphatic dicarboxylic acid such as oxalic acid; and, particularly, optionally C₁₋₂₀ alkyl substituted aromatic sulfonic acid, such as benzenesulfonic acid, p-toluenesulfonic acid and dodecylbenzene sulfonic acid.

These electroconductive polymers are also preferably selectable from the commercially available ones. Examples of the commercially available products include electroconductive polymer composed of poly(3,4-ethylene dioxythiophene) and polystyrenesulfonic acid (abbreviated as PEDOT-PSS, hereinafter) from H.C. Starck GmbH under the trade name of Clevios Series, from Aldrich under the trade names of PEDOT-PSS 483095 and 560596, and from Nagase ChemteX Corporation under the trade name of Denatron Series. Polyaniline is commercially available from Nissan Chemical Industries, Ltd. under the trade name of ORMECON Series. Also these agents are preferably used in the present embodiment.

The second dopant may contain an organic compound. The organic compound adoptable to the present embodiment is not specifically limited, and is appropriately selectable from publicly-known compounds, preferably exemplified by oxygen-containing compound. The oxygen-containing compound is not specifically limited so long as it contains oxygen, and is exemplified by hydroxy group-containing compound, carbonyl group-containing compound, ether group-containing compound, and sulfoxide group-containing compound. The hydroxy group-containing compound is exemplified by ethylene glycol, diethylene glycol, propylene glycol, trimethylene glycol, 1,4-butanediol, and glycerin. Among them, ethylene glycol and diethylene glycol are preferable. The carbonyl group-containing compound is exemplified by isophorone, propylene carbonate, cyclohexanone, and γ-butyrolactone. The ether group-containing compound is exemplified by diethylene glycol monoethylether. The sulfoxide group-containing compound is exemplified by dimethyl sulfoxide. These compounds may be used alone, or in combination of two or more species, where it is preferable to use at least one species selected from dimethyl sulfoxide, ethylene glycol, and diethylene glycol.

### (Transparent Base)

The transparent base is a sheet-like article capable of holding thereon the electroconductive layer. For the purpose of obtaining the transparent electroconductive film, the base preferably used herein has a total luminous transmittance in the visible wavelength region of 80% or larger, when measured in compliance with JIS K 7361-1-1997 (Plastics-Determination of the Total Luminous Transmittance of Transparent Materials).

The base preferably used herein has an excellent flexibility, has a sufficiently small dielectric loss coefficient, and shows a microwave absorption smaller than that of the electroconductive layer.

Preferable examples of the base include resin base and resin film. Transparent resin film is preferably used, from the viewpoint of productivity, and performances such as lightness in weight and flexibility. The transparent resin film herein means a film showing a total luminous transmittance in the visible wavelength region of 50% or larger, when measured in compliance with JIS K 7361-1-1997 (Plastics-Determination of the Total Luminous Transmittance of Transparent Materials).

The transparent resin film preferably used in the present embodiment is appropriately selectable from publicly-known ones with a variety of materials, geometries, structures and thickness, without special limitation. Examples of the transparent resin film include polyester-based resin film such as polyethylene terephthalate (PET), polyethylene naphthalate, and modified polyester; polyolefinic resin film such as polyethylene (PE) resin film, polypropylene (PP) resin film, polystyrene resin film, and cycloolefinic resin film; vinyl-based resin film such as polyvinyl chloride film, and polyvinylidene chloride film; polyether ether ketone (PEEK) resin film, polysulfone (PSF) resin film, polyethersulfone (PES) resin film, polycarbonate (PC) resin film, polyamide resin film, polyimide resin film, acryl resin film, and triacetylcellulose (TAC) resin film.

The resin film having a total luminous transmittance of 80% or larger may preferably be used as the film base in the present embodiment. Among others, biaxially stretched polyethylene terephthalate film, biaxially stretched polyethylene naphthalate film, polyethersulfone film, and polycarbonate film are preferable from the viewpoint of transparency, heat resistance, handlability, strength and cost. Biaxially stretched polyethylene terephthalate film, and biaxially stretched polyethylene naphthalate film are more preferable.

The base used in the present embodiment may be surface-treated, or may be provided with an adhesion assisting layer on the surface thereof, for the purpose of ensuring desirable levels of wetting and adhesiveness with the coating liquid. Any publicly known techniques may be adoptable to the surface treatment and the adhesion assisting layer.

Examples of the surface treatment include surface activation treatment such as corona discharge treatment, flame hardening, ultraviolet irradiation, induction hardening, glow discharge treatment, activated plasma treatment, and laser treatment.

Examples of the adhesion assisting layer include those composed of polyester, polyamide, polyurethane, vinyl-based copolymer, butadiene-based copolymer, acryl-based copolymer, vinylidene-based copolymer, and epoxy-based copolymer. The adhesion assisting layer may be configured by a single layer, or may be two or more layers for improved adhesiveness.

The film base may have, on the top surface or the back surface thereof, a cover film composed of an inorganic material, organic material, or a hybrid material of the both. The cover film is preferably a barrier film showing a water vapor transmission rate (25±0.5° C., (90±2)% RH) of 1×10⁻³ g/(m²·24 h) or smaller when measured in compliance with JIS K 7129-1992, and more preferably a high-barrier film showing an oxygen transmission rate of 1×10⁻³ ml/m²·24 h·atm or smaller when measured in compliance with JIS K 7126-1987, and a water vapor transmission rate (25±0.5° C., (90±2)% RH) of 1×10⁻³ g/(m²·24 h) or smaller.

Materials, which compose the barrier film to be formed on the top surface or the back surface of the film base so as to ensure high barrier performance, may be anything so long as they can suppress intrusion of substances such as water, oxygen and so forth which possibly degrade the device. Silicon monoxide, silicon dioxide and silicon nitride, for example, may be used. For the purpose of further reforming brittleness of the film, it is preferable to stack these inorganic layer with a layer composed of an organic material. While the order or stacking of the inorganic layer and the organic layer is not specifically limited, it is preferable to alternately stack the both plural number of times.

### (Metal-Containing Electroconductive Layer)

The transparent electroconductive film in the present embodiment may have a metal material-containing electroconductive layer (the first electroconductive layer in FIG. 1) formed on the base, besides the electroconductive layer (the second electroconductive layer in FIG. 1) which contains the electroconductive polymer and the dissociable group-containing, self-dispersing polymer dispersible into aqueous solvent.

The metal material is not specifically limited so long as they show electroconductivity, and is exemplified by metals such as gold, silver, copper, iron, cobalt, nickel, and chromium, and also by alloy. In particular, from the viewpoint of readiness of patterning as described later, geometry of the metal material is preferably fine particle or nanowire. From the viewpoint of electroconductivity, the metal material is preferably silver or copper, and more preferably silver.

The first electroconductive layer in the present embodiment is formed on the base, so as to give a pattern having openings, aiming at forming the transparent electroconductive film. The openings herein correspond to portions of the base having no metal material, and are given as light-transmissive windows.

Geometry of the pattern is not specifically limited, so that the first electroconductive layer may have a stripe, mesh or random network pattern. Ratio of openings is preferably 80% or larger, from the viewpoint of transparency.

The ratio of openings herein means a ratio of area not occupied by the non-light-transmissive first electroconductive layer relative to the total area. For example, given that the first electroconductive layer has a stripe or mesh pattern with a line width of 100 μm and a space of 1 mm, the ratio of openings is approximately 90%.

The width of the fine wire of the pattern is preferably 10 to 200 μm. The width of fine wire smaller than 10 μm may fail to obtain a desired level of electroconductivity, whereas the width of the fine wire exceeding 200 μm may degrade the transparency. The height of the fine wire is preferably 0.1 to 10 μm. The height of fine wire smaller than 0.1 μm may fail to obtain a desired level of electroconductivity, whereas the height exceeding 10 μm may induce current leakage, and non-uniform thickness distribution of functional layers in manufacturing of the organic electronic devices.

Methods of forming the first electroconductive layer having a stripe- or mesh-pattern may be any of publicly known methods, without special limitation. For example, the electrode may be formed by forming a metal layer over the entire surface of the base, followed by a publicly-known lithographic process. More specifically, an electroconductive layer may be formed by one, or two or more chemical or physical processes selected from printing, deposition, sputtering, plating and so forth, over the entire surface of the base, or a metal foil may be stacked on the base using an adhesive, and then patterned by publicly known photolithographic and etching processes, to thereby give a desired stripe or mesh pattern.

Other possible methods include a method of printing an ink containing a metal fine particle by screen printing so as to give a desired pattern; a method of coating a catalyst ink, allowing plating to proceed thereon, by gravure printing or ink jet printing so as to give a desired pattern, followed by plating; and still alternatively, a method making use of a silver halide photographic technique. The method making use of a silver halide photographic technique may be implemented, typically referring to the description in paragraphs [0076] to [0112] and Examples of JP-A-2009-140750. The method based on gravure printing of a catalyst ink and succeeding plating may be implemented, typically referring to the description in JP-A-2007-281290.

The random network structure may be formed typically by the method described in Published Japanese Translation of PCT International Publication for Patent Application No. 2005-530005, according to which a random network structure of electroconductive fine particle is formed spontaneously, by coating and drying a liquid containing a metal fine particle.

Another possible method is described, for example, in Published Japanese Translation of PCT International Publication for Patent Application No. 2009-505358, according to which a coating liquid which contains a metal nanowire is coated and dried, to thereby form a random network structure of the metal nanowire.

The metal nanowire herein means a fibrous article mainly composed of a metal element. In particular, in the context of the present embodiment, the metal nanowire means a large number of fibrous articles having a minor axis ranging from the atomic scale to nanometer scale.

The metal nanowire preferably has an average length of 3 μm or longer, in view of forming a long electric conduction path by a single metal nanowire, more preferably 3 to 500 μm, and particularly preferably 3 to 300 μm. In addition, the relative standard deviation of length is preferably 40% or smaller. While the average minor axis is not specifically limited, it is preferably small from the viewpoint of transparency, but is preferably large from the viewpoint of electroconductivity. The average minor axis of the metal nanowire is preferably 10 to 300 nm, and more preferably 30 to 200 nm. In addition, the relative standard deviation of minor axis is preferably 20% or smaller. The coating weight of the metal nanowire is preferably 0.005 to 0.5 g/m², and more preferably 0.01 to 0.2 g/m².

Metals adoptable to the metal nanowire include copper, iron, cobalt, gold, and silver, wherein silver is preferable from the viewpoint of electroconductivity. While a single species of the metal may be used alone, a major constituent metal may be combined with one or more species of other metals at an arbitrary ratio, for the purpose of achieving desirable levels of electroconductivity and stability (resistance of metal nanowire against sulfation and oxidation, and migration resistance) at the same time.

The metal nanowire may be manufacturing by any of publicly known methods such as liquid phase process and vapor phase process, without special limitation. For example, methods of manufacturing silver nanowire may be referred to Adv. Mater., 2002, Vol. 14, p. 833-837, and Chem. Mater., 2002, Vol. 14, p. 4736-4745; methods of manufacturing gold nanowire may be referred to JP-A-2006-233252 and so forth; methods of manufacturing copper nanowire may be referred to JP-A-2002-266007 and so forth; and methods of manufacturing cobalt nanowire may be referred to JP-A-2004-149871 and so forth. In particular, the above-described methods of manufacturing silver nanowire are preferable, since the silver nanowire is readily producible in aqueous solution, and also since silver has the largest electroconductivity among metals.

Sheet resisivity of the fine wire composed of the metal material is preferably 100Ω/□ or smaller, and more preferably 20Ω/□ or smaller in view of further expansion of the device area. The surface resistivity is measurable typically in compliance with JIS K 6911, ASTM D257 and so forth, and is readily measurable using a commercially available surface resistivity meter.

The fine wire composed of the metal material is preferably annealed, so long as it does not damage the film base. Such annealing is particularly preferable, since the metal fine particle and the metal nanowire are well fused, to thereby enhance the electroconductivity of the first electroconductive layer.

### (Coating, Heating, Drying)

The transparent electroconductive layer in the present embodiment may be formed by coating, on the base, a coating liquid containing the above-described electroconductive polymer, and the dissociable group-containing, self-dispersing polymer dispersible into aqueous solvent, followed by heating and drying. For the case where the transparent electroconductive film contains the first electroconductive layer composed of fine metal material, the coating liquid may be coated on the base having formed thereon the first electroconductive layer, followed by heating and drying to form the second electroconductive layer. The coating liquid may completely cover the first electroconductive layer, or may partially cover it, or still alternatively, may be brought into contact therewith.

The coating liquid containing the electroconductive polymer, and the dissociable group-containing, self-dispersing polymer dispersible into aqueous solvent may be coated by any of printing methods such as gravure printing, flexographic printing and screen printing; and any of coating methods such as roll coating, bar coating, dip coating, spin coating, casting, die coating, blade coating, gravure coating, curtain coating, spray coating, doctor coating and ink jet coating.

When the transparent electroconductive film, having the second electroconductive layer, is formed so as to partially cover the first electroconductive layer, or so as to be brought into contact therewith, it suffices that a first electroconductive layer is formed on a transfer film by the method described in the above, the second electroconductive layer is stacked thereon, and the stack is then transferred onto the above-described film base.

Another possible method is such as forming the second electroconductive layer, in the openings of the first electroconductive layer, typically by ink jet process.

The transparent electroconductive layer is characterized by the self-dispersing polymer contained therein. By virtue of this configuration, excellent levels of electroconductivity, transparency and film strength may be obtained.

By forming the thus-configured electroconductive layer in the present embodiment, an excellent level of electroconductivity, which cannot be achieved by fine wire alone by itself, composed of metal or metal oxide, or by electroconductive polymer layer alone by itself, may be obtained uniformly all over the transparent electroconductive film.

As for ratio of the electroconductive polymer and the dissociable group-containing, self-dispersing polymer in the transparent electroconductive layer, 30 to 900 parts by mass, and more preferably 100 parts by mass or more, of the dissociable group-containing, self-dispersing polymer is preferably used per 100 parts by mass of electroconductive polymer, from the viewpoint of prevention of current leakage, enhancement in the electroconductivity of the dissociable group-containing, self-dispersing polymer, and the transparency.

The thickness of the dried transparent electroconductive layer is preferably 30 to 2000 nm. From the viewpoint of electroconductivity, the thickness is preferably 100 nm or larger, and more preferably 200 nm or larger from the viewpoint of smoothness of the film surface, whereas more preferably 1000 nm or smaller from the viewpoint of transparency.

The transparent electroconductive layer may optionally be dried after coating. The drying is preferably proceeded in a temperature range so as not to damage the base and the electroconductive layer, typically at 80 to 120° C. for 10 seconds to 10 minutes, while the conditions are not specifically limited. In this way, the cleaning durability and solvent durability of the film may be improved to a considerable degree, and thereby the performance of the device using the film may be improved. Effects including decrease in the drive voltage and elongation of service life are particularly expected for the organic EL device.

The coating liquid may further contains additives. The additives adoptable herein include plasticizer, stabilizers such as antioxidant and anti-sulfurizing agent, surfactant, solubility enhancer, polymerization inhibitor, and colorants such as dye and pigment. From the viewpoint of further improving the workability such as coatability, solvent (for example, water, and organic solvents such as alcohols, glycols, cellosolves, ketones, esters, ethers, amides, hydrocarbons and so forth) may be contained.

In the present embodiment, Ry and Ra denoting the smoothness of the surface of the transparent electroconductive layer may be given as Ry=maximum height (difference of height between the apex and valley of the surface) and Ra=arithmetical mean roughness, in compliance with surface roughness specified by JIS B 601-1994. In the transparent electroconductive film of the present embodiment, preferable ranges of the smoothness of the surface of the transparent electroconductive layer are expressed as Ry-50 nm and Ra≦10 nm. Ry and Ra in the present embodiment may be measured by using a commercially-available atomic force microscope (AFM), typically according to the method below.

The AFM adoptable herein is SPI3800N probe station combined with SPA400 multifunction unit from Seiko Instruments Inc. A sample having a size of approximately 1-cm square is set on a horizontal sample stage of a piezo scanner, a cantilever is brought into proximity with the surface of sample as close to a position where the interatomic force can effect, and then scanned in the XY-direction, wherein the displacement of the cantilever in the Z-direction is sensed by the piezo scanner to sense the asperity of the surface of the sample. The piezo scanner adoptable herein is capable of scanning over the range of 20 μm in the XY-direction and 2 μm in the Z-direction. The cantilever adoptable herein is a silicon cantilever SI-DF20 from Seiko Instruments Inc., with a resonance frequency of 120 to 150 kHz, and a spring constant of 12 to 20 N/m, used under DFM (Dynamic Force Mode). A 80×80 μm measurement area is measured at a scanning frequency of 1 Hz.

In the present embodiment, Ry is preferably 50 nm or smaller, and more preferably 40 nm or smaller. Similarly, Ra is preferably 10 nm or smaller, and more preferably 5 nm or smaller.

In the present embodiment, the transparent electroconductive film preferably has a total luminous transmittance of 60% or larger, more preferably 70% or larger, and particularly preferably 80% or larger. The total luminous transmittance may be measured by any of publicly known methods using a spectrophotometer. Electric resistance of the transparent electroconductive layer of the transparent electroconductive film of the present embodiment is preferably 1000Ω/□ or smaller in terms of surface resistivity, and more preferably 100Ω/□ or smaller. In view of applying the transparent electroconductive film to current-driven, opto-electronic devices, the electric resistance is preferably 50Ω/□ or smaller, and particularly preferably 10Ω/□ or smaller. By adjusting the electric resistance to 10³Ω/□ or smaller, the transparent electroconductive film may preferably function in various types of opto-electronic devices.

The surface resistivity is measurable typically in compliance with JIS K 7194 (“Testing Method for Resistivity of Conductive Plastics with a Four-Point Probe Array”) or the like, and is readily measurable using a commercially available surface resistivity meter.

The thickness of the transparent electroconductive film of the present embodiment is not specifically limited, and is appropriately selectable depending on purposes. The thickness is preferably 10 μm or smaller in general, wherein the thinner the better, since the transparency and flexibility may be improved.

### <<Organic EL Device>>

The organic EL device of the present embodiment is characterized by having the transparent electroconductive film of the present embodiment.

The organic EL device of the present embodiment has an organic layer containing the organic luminescent layers, and a transparent electrode made of the transparent electroconductive film of the present embodiment.

The organic EL device of the present embodiment preferably uses the transparent electrode as an anode. The organic luminescent layer and the cathode herein may be formed by adopting materials and configurations generally adopted.

Examples of configuration of the organic EL device include anode/organic luminescent layer/cathode, anode/hole transport layer/organic luminescent layer/electron transport layer/cathode, anode/hole injection layer/hole transport layer/organic luminescent layer/electron transport layer/cathode, anode/hole injection layer/organic luminescent layer/electron transport layer/electron injection layer/cathode, and anode/hole injection layer/organic luminescent layer/electron injection layer/cathode.

Examples of the luminescent material and the dopant adoptable to the organic luminescent layer in the present embodiment include anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, quinoline metal complex, tris(8-hydroxyquinolinate) aluminum complex, tris(4-methyl-8-quinolinate) aluminum complex, tris(5-phenyl-8-quinolinate) aluminum complex, aminoquinoline metal complex, benzoquinoline metal complex, tri-(p-terphenyl-4-yl)amine, 1-aryl-2,5-di(2-thienyl)pyrrole derivative, pyran, quinacridone, rubrene, distylbenzene derivative, distylarylene derivative, and various fluorescent dyes, rare earth metal complexes, and phosphorescent materials, while not being limited thereto. The organic luminescent layer preferably contains 90 to 99.5 parts by mass of luminescent material selected from the above-listed compounds, and 0.5 to 10 parts by mass of the dopant.

The organic luminescent layer is manufactured using the above-described materials, by any of publicly known methods including deposition, coating, and transfer. The thickness of the organic luminescent layer is preferably 0.5 to 500 nm, and particularly preferably 0.5 to 200 nm.

The organic EL device of the present embodiment is typically adoptable to self-emitting display device, backlight for liquid crystal display device, and illumination device. The organic EL device of the present embodiment is preferably used for illumination purposes, since it can uniformly emit light without causing variability in the luminance.

The transparent electroconductive film of the present embodiment is excellent both in the electroconductivity and transparency, and is preferably adoptable to various opto-electronic devices such as liquid crystal display device, organic electroluminescent device, inorganic electroluminescent device, electronic paper, organic solar battery, and inorganic solar battery; and in the field of electromagnetic shield and touchscreen. Among others, it is particularly preferably adoptable to the transparent electrodes for the organic EL device and organic thin film solar battery device, to which the smoothness of the transparent electrode surface is strictly demanded.

### EXAMPLES

The present embodiment will specifically be explained below, without limiting the present embodiment. Note that “part (s)” and “%” used in the description of Examples stand for “part (s) by mass” and “% by mass”, unless otherwise specifically stated.

### Exemplary Synthesis 1

### Synthesis of Binder Resin P-1: Comparative Compound

### [Synthesis of Poly-2-Hydroxyethyl Acrylate (P-1)]

In a 300 ml recovery flask, 5.0 g (43.1 mmol, F.W.=116.12) of 2-hydroxyethyl acrylate (from Tokyo Chemical Industry Co. Ltd.), 0.7 g (4.3 mmol, F.W.=164.21) of 2,2′-azobis(2-methylisopropionitrile) and 100 ml of tetrahydrofuran were placed, and the mixture was refluxed under heating for 8 hours. The mixture was then cooled to room temperature, and dropped into another flask containing 2.0 L of methyl ethyl ketone under vigorous stirring. After one-hour stirring of the mixture, methyl ethyl ketone was decanted off, and the polymer adhered on the wall of the flask was washed three times with 100 ml each of methyl ethyl ketone. The polymer was then dissolved into 100 ml of tetrahydrofuran, the solution was transferred to a 200-ml flask, and tetrahydrofuran was vaporized off under reduced pressure using a rotary evaporator. The product was kept at 80° C. for 3 hours under reduced pressure so as to remove the residual tetrahydrofuran, to thereby obtain 4.1 g of binder resin P-1 (82% yield) having a number-average molecular weight of 57,800, and molecular weight distribution of 1.24.

The structure and molecular weight were measured by ¹H-NMR (400 MHz, using an instrument from JEOL, Ltd.), and gel permeation chromatography (GPC) (Waters 2695, from Waters), respectively. Four grams of the thus-obtained P-1 was dissolved in 16.0 g of pure water, to thereby prepare a 20% aqueous solution of P-1.

### <Measurement Conditions of GPC>

### Apparatus: Waters 2695 (Separation Module)

### Detector: Waters 2414 (Refractive Index Detector)

### Column: Shodex Asahipak GF-7M HQ

Eluent: dimethylformamide (containing 20 mM of LiBr)
Flow rate: 1.0 ml/min

### Temperature: 40° C.

### <Manufacturing of Base>

On one surface of a 100-μm-thick polyethylene terephthalate film (Cosmoshine A4100, from Toyobo Co. Ltd.) having no undercoating layer formed thereon, a UV curable organic/inorganic hybrid hard coat material OPSTAR Z7501, from JSR Corporation, was coated using a wire bar so as to adjust the average dry film thickness to 4 μm, the coated film was dried at 80° C. for 3 minutes, and was allowed to cure under an aerial environment, using a high-pressure mercury lamp under a curing energy of 1.0 J/cm², to thereby form a smoothening layer.

Next, on the sample having the smoothening layer formed thereon, a gas barrier layer was formed as described below.

### (Coating Liquid for Forming Gas Barrier Layer)

A 20%-by-mass dibutyl ether solution of perhydropolysilazane (PHPS) (Aquamica NN320, from AZ Electronic Materials) was coated using a wireless bar so as to adjust the (average) dry film thickness to 0.30 μm, to thereby obtain a coated sample.

### (First Process; Drying)

The obtained coated sample was dried in an atmosphere of 85° C., 55% RH for one minute, to thereby obtain a dried sample.

### (Second Process; Dehumidification)

The dried sample was further kept in an atmosphere of 25° C., 10% RH (dew point=−8° C.) for 10 minutes for dehumidification.

### (Modification A)

The dehumidified sample was modified under the conditions below, to thereby form a gas barrier layer. The modification was proceeded at a dew point of −8° C.

### (Modifying Apparatus)

An excimer irradiation apparatus Model MECL-M-1-200 from M.D.COM., Inc., λ=172 nm, with a Xe-filled lamp, was used.

The sample fixed on a movable stage was modified under the conditions below.

### (Conditions of Modification)

Excimer light energy=60 mW/cm² (172 nm)
Distance between sample and light source=1 mm
Stage heating temperature=70° C.
Oxygen concentration in irradiation chamber=1%
Excimer light irradiation time=3 seconds

A base for the transparent electroconductive film, having a gas barrier property, was thus manufactured.

### <Formation of First Electroconductive Layer>

A first electroconductive layer was formed on the other surface, having no gas barrier layer formed thereon, of the above-obtained base having a gas barrier property, according to the method described below.

### (Fine Wire Lattice)

A fine wire lattice (metal material) was formed by gravure printing or using silver nanowire, as described below.

### (Gravure Printing)

A silver nanoparticle paste (M-Dot SLP: from Mitsuboshi Belting, Ltd.) was coated using a gravure printer/tester K303 Multicoater from RK Print Coat Instruments, Ltd., so as to give a fine wire lattice pattern with a line width of 50 μm, a line height of 1.5 μm, and a space of 1.0 mm, and then dried at 110° C. for 5 minutes.

### (Random Network Structure Formed by Using Nanowire)

A random network structure was manufactured by using a silver nanowire, as described below.

A silver nanowire dispersion was coated using a bar coater, so as to give a coating weight of silver nanowire of 0.06 g/m², and dried at 110° C. for 5 minutes, to thereby manufacture a silver nanowire-coated base.

The silver nanowire dispersion was prepared referring to the method described in Adv. Mater., 2002, vol. 14, p. 833-837, according to which the silver nanowire having an average minor axis of 75 nm and an average length of 35 μm was manufactured using polyvinyl pyrrolidone K30 (MW=50,000, from ISP Inc.), the silver nanowire was collected over a ultrafilter, washed, and re-dispersed into an aqueous solution containing 25% by mass, relative to silver, of hydroxypropylmethyl cellulose 60SH-50 (from Shin-Etsu Chemical Co. Ltd.).

### Example 1

### Manufacturing of Transparent Electroconductive Film

<Manufacturing of Transparent Electroconductive film TC-101>

On one surface of the base where the first electroconductive layer was thus-formed by gravure printing and on the first electroconductive layer, coating liquid A described below was coated by extrusion, while adjusting the slit width of an extrusion head so as to give a dried film thickness of 300 nm, and the coated film was dried at 110° C. for 5 minutes. The second electroconductive layer, composed of the electroconductive polymer and the binder resin dispersible into aqueous solvent, was then formed thereon, and the obtained film was cut into 8×8 cm pieces. The obtained film was baked in an oven at 110° C. for 30 minutes, to thereby manufacture a transparent electroconductive film TC-101.

### <Formation of Second Electroconductive Layer>

### (Coating Liquid A)

Electroconductive polymer: PEDOT-PSS Clevios PH510 (solid content=1.89%, from H.C. Starck GmbH) 1.59 g
Binder: Polysol FP3000 (aqueous solution with a solid content of 54.4%) 0.13 g
Dimethyl sulfoxide (DMSO, one-tenth of the mass of electroconductive polymer solution) 0.16 g

### (Manufacturing of Transparent Electroconductive Films TC-102 to TC-106)

Transparent electroconductive films TC-102 to TC-106 were manufactured similarly to the transparent electroconductive film TC-101, except that binders listed in Tables 1-1 and 1-2 were used in place of Polysol which is a binder of the coating liquid A, and that the amount of addition to the coating liquid A was changed so as to adjust the solid content to 70 mg.

### (Manufacturing of Transparent Electroconductive Film TC-107)

A transparent electroconductive film TC-107 was manufactured similarly to the transparent electroconductive film TC-101, except that Plascoat RZ570 was used in place of Polysol FP3000, and that 0.5 g of polyaniline M (solid content=6.0%, from TA Chemical Co.) was used in place of PEDOT-PSS Clevios PH510 (solid content=1.89%, from H.C. Starck GmbH) in the coating liquid A.

### (Manufacturing of Transparent Electroconductive Film TC-108) (Random Network Structure)

The silver nanowire dispersion was prepared referring to the method described in Adv. Mater., 2002, Vol. 14, p. 833-837, according to which the silver nanowire having an average minor axis of 75 nm and an average length of 35 μm was manufactured using polyvinyl pyrrolidone K30 (MW=50,000, from ISP Inc.), the silver nanowire was collected over a ultrafilter, washed, and re-dispersed into an aqueous solution containing 25% by mass, relative to silver, of hydroxypropylmethyl cellulose 60SH-50 (from Shin-Etsu Chemical Co. Ltd.).

A random network structure was formed by using a silver nanowire, as described below.

A silver nanowire dispersion was coated using a bar coater, so as to give a coating weight of silver nanowire of 0.06 g/m², and dried at 110° C. for 5 minutes, to thereby manufacture a silver nanowire-coated base.

On one surface of the base where the first electroconductive layer was thus-formed using the silver nanowire and on the first electroconductive layer, a second electroconductive layer was formed, according to a method similar to that for manufacturing the transparent electroconductive film TC-101, using a coating liquid A but containing Plascoat RZ570, as a binder, in place of Polysol FP3000, and the product was cut into 8×8 cm pieces. The thus-obtained film was baked in an oven at 110° C. for 30 minutes, to thereby manufacture a transparent electroconductive film TC-108.

### (Manufacturing of Transparent Electroconductive Film TC-109) (Copper Mesh Base)

A copper mesh was formed as an auxiliary electrode on the base as described below, and then patterned using a metal particle removing liquid, to thereby manufacture a copper mesh substrate.

Catalyst ink JIPD-7 from Morimura Chemicals, Ltd. containing a palladium nanoparticle was added with self-dispersing carbon black solution CAB-O-JET300 from Cabot Corporation, so as to adjust the ratio of carbon black relative to the catalyst ink to 10.0% by mass, and was further added with Surfynol 465 (from Nisshin Chemical Co. Ltd.), to thereby prepare an electroconductive ink having a surface tension at 25° C. of 48 mN/m.

The electroconductive ink was fed to an ink jet printer having an ink jet recording head which is configured by a pressurizing unit, electric field application unit, and a piezoelectric head having a nozzle diameter of 25 μm, a drive frequency of 12 kHz, number of nozzles of 128, and a nozzle density of 180 dpi (dpi means “dots per inch”, or the number of dots per 2.54 cm), jetted to form a lattice-patterned electroconductive fine wire having a line width of 10 μm, a dry film thickness of 0.5 μm, and a line-to-line space of 300 μm, on the base, and then dried.

Next, the obtained base was dipped in a high-speed electroless copper plating bath CU-5100 from Meltex Inc., at 55° C. for 10 minutes for electroless plating, and then washed. An auxiliary electrode having a thickness of plating of 3 μm was thus formed.

The second electroconductive layer was formed by a method similar to that for manufacturing the transparent electroconductive film TC-101, except that the coating liquid A containing, as the binder, Plascoat RZ570 in place of Polysol FP3000 was coated on the base having the copper mesh formed thereon and on the copper mesh. The product was cut into 8×8 cm pieces, and baked in an oven at 110° C. for 30 minutes, to thereby manufacture a transparent electroconductive film TC-109.

### (Manufacturing of Transparent Electroconductive Films TC-110 to TC-114)

Transparent electroconductive films TC-110 to TC-114 of Comparative Examples were manufactured similarly to the transparent electroconductive film TC-101, except that binders listed in Tables 1-1 and 1-2 were used as the binder of the coating liquid A, in place of Polysol FP3000.

Note that Nypol LX430, Nypol LX433C, and Nypol LX435 used as the binder for TC-110 to TC-112 were not the dissociable group-containing, self-dispersing polymer in the context of the present embodiment, and were therefore used together with a surfactant for improving dispersibility.

### (Manufacturing of Comparative Transparent Electroconductive Film TC-115)

A transparent electroconductive film TC-115 was manufactured similarly to transparent electroconductive film TC-101, except that the binder in the coating liquid A was not used.

### <<Evaluation of Transparent Electroconductive Film>>

The glass transition point (Tg) of the binders were measured as described below. Also film geometry, transparency, surface resistivity (electroconductivity), surface roughness, and film strength of the thus-obtained transparent electroconductive film were evaluated as described below. In order to evaluate stability of the transparent electroconductive film, the geometry, transparency, surface resistivity, surface roughness, and strength of the film, after being allowed to stand under an environment for forced degradation at 80° C., 90% RH for 5 days, were evaluated.

### (Measurement of Tg)

Tg was measured using a scanning differential calorimeter (Model DSC-7, from PerkinElmer Inc.) at a temperature elevation rate of 10° C./min. in compliance with JIS K 7121-1987.

### (Transparency)

Total luminous transmittance was measured using a Haze Meter NDH5000 from Tokyo Denshoku Co. Ltd., in compliance with JIS K 7361-1-1997, and the transparency was evaluated according to the criteria below. Taking application to electronic devices into account, the transparency is preferably 75% or larger.

[symbol]

: (double circle) 80% or larger;
◯: (single circle) 75% or larger, smaller than 80%;
Δ: (triangle) 70% or larger, smaller than 75%; and
x: (X) smaller than 70%.

### (Surface Resistivity)

The surface resistivity was measured using a resistivity meter (Loresta GP (Model MCP-T610), from Mitsubishi Chemical Analytech Co. Ltd.) in compliance with JIS K 7194-1994. The surface resistivity is preferably 100Ω/□ or smaller, and more preferably 30Ω/□ or smaller, in view of expanding the area of the organic electronic devices.

### (Surface Roughness (Ra, Ry))

Surface roughness was measured using a sample having a size of approximately 1 cm square, and an AFM (SPI3800N probe station, combined with SPA400 multifunction unit, from Seiko Instruments Inc.), according to the above described method (in compliance with the surface roughness specified by JIS B 601-1994).

### (Film Strength)

The film strength of the electroconductive layer was evaluated by a tape peeling test.

A cycle of placement and peeling off of Scotch tape, from 3M Company, on and from the surface of the electroconductive layer, was repeated 10 times, exfoliation of the electroconductive layer was visually observed, and the result was evaluated according to the criteria below:

[symbol] : (double circle) no change observed after placement/peeling-off repeated 5 times;

◯: (single circle) no change observed after placement/peeling-off repeated 3 times;

Δ: (triangle) exfoliation observed after a single time of placement/peeling-off, with 80% or more of the pattern remained; and

x: (X) exfoliation observed after a single time of placement/peeling-off, with less than 80% of the pattern remained.

Results are shown in Tables 1-1 and 1-2 below.

TABLE 1-1

| | | | | | | | | EVALUATION | |
|---|---|---|---|---|---|---|---|---|---|
| | | | | | | | | BEFORE FORCED | |
| TRANSPARENT | BINDER RESIN | | | | | ELECTRO- | | DEGRADATION TEST | |
| ELECTRO- | | SOLID | | DISSO- | | CONDUCTIVE | | | SURFACE |
| CONDCTIVE | | CONTENT | | CIATIVE | TC | POLYMER | GRID | TRANS- | RESISTIVITY |
| FILM NO. | TYPE | [%] | SURFACTANT | GROUP | [° C.] | TYPE | TYPE | PARENCY | [Ω/□] |
| TC-101 | FP3000 | 54.4 | NO | ANION | 40 | 1 | Ag FINE | ◯ | 2 |
| | | | | | | | WIRE | | |
| TC-102 | MD1245 | 30 | NO | ANION | 61 | 1 | Ag FINE | ◯ | 2 |
| | | | | | | | WIRE | | |
| TC-103 | MD1500 | 30 | NO | ANION | 77 | 1 | Ag FINE | ◯ | 2 |
| | | | | | | | WIRE | | |
| TC-104 | MD2000 | 40 | NO | ANION | 67 | 1 | Ag FINE | ◯ | 2 |
| | | | | | | | WIRE | | |
| TC-105 | RZ105 | 25 | NO | ANION | 52 | 1 | Ag FINE | ◯ | 2 |
| | | | | | | | WIRE | | |
| TC-106 | RZ570 | 25 | NO | ANION | 60 | 1 | Ag FINE | ◯ | 2 |
| | | | | | | | WIRE | | |
| TC-107 | RZ570 | 25 | NO | ANION | 60 | 2 | Ag FINE | ◯ | 5 |
| | | | | | | | WIRE | | |

| | EVALUATION | | | | | | | | |
|---|---|---|---|---|---|---|---|---|---|
| | | | | AFTER FORCED DEGRADATION TEST | | | | | |
| TRANSPARENT | BEFORE FORCED | | | [80° C., 90% RH (5 DAYS)] | | | | | |
| ELECTRO- | DEGRADATION TEST | | | | SURFACE | | | | |
| CONDCTIVE | Ry | Ra | FILM | TRANS- | RESISTIVITY | Ry | Ra | FILM | |
| FILM NO. | [nm] | [nm] | STRENGTH | PARENCY | [Ω/□] | [nm] | [nm] | STRENGTH | REMARK |
| TC-101 | 22 | 4 | ◯ | ◯ | 11 | 31 | 9 | ◯ | EXAMPLE |
| TC-102 | 24 | 4 | ⊚ | ◯ | 5 | 27 | 5 | ⊚ | EXAMPLE |
| TC-103 | 23 | 4 | ⊚ | ◯ | 9 | 26 | 5 | ⊚ | EXAMPLE |
| TC-104 | 23 | 3 | ⊚ | ◯ | 6 | 25 | 6 | ⊚ | EXAMPLE |
| TC-105 | 22 | 4 | ⊚ | ◯ | 4 | 28 | 7 | ⊚ | EXAMPLE |
| TC-106 | 23 | 3 | ⊚ | ◯ | 7 | 29 | 7 | ⊚ | EXAMPLE |
| TC-107 | 29 | 5 | ⊚ | ◯ | 10 | 39 | 9 | ⊚ | EXAMPLE |

FP3000: POLYSOL FP3000
MD1245: VYLONAL MD1245
RZ105: PLASCOAT RZ105
LX430: NYPOL LX430
MD1480: VYLONAL MD1480
1: POLYTHIOPHENE
MD1500: VYLONAL MD1500
RZ570: PLASCOAT RZ570
LX433C: NYPOL LX433C
2: POLYANILINE
MD2000: VYLONAL MD2000
RZ571: PLASCOAT RZ571
LX435: NYPOL LX435

TABLE 1-2

| | | | | | | | | EVALUATION | |
|---|---|---|---|---|---|---|---|---|---|
| | | | | | | | | BEFORE FORCED | |
| TRANSPARENT | BINDER RESIN | | | | | ELECTRO- | | DEGRADATION TEST | |
| ELECTRO- | | SOLID | | DISSO- | | CONDUCTIVE | | | SURFACE |
| CONDCTIVE | | CONTENT | | CIATIVE | TC | POLYMER | GRID | TRANS- | RESISTIVITY |
| FILM NO. | TYPE | [%] | SURFACTANT | GROUP | [° C.] | TYPE | TYPE | PARENCY | [Ω/□] |
| TC-108 | RZ570 | 25 | NO | ANION | 60 | 1 | Ag | ⊚ | 10 |
| | | | | | | | NANOWIRE | | |
| TC-109 | RZ571 | 26 | NO | ANION | 61 | 1 | Cu | ◯ | 2 |
| | | | | | | | MESH | | |
| TC-110 | LX430 | 49 | YES | ANION | 12 | 1 | Ag FINE | ◯ | 17 |
| | | | | | | | WIRE | | |
| TC-111 | LX433C | 50 | YES | ANION | 50 | 1 | Ag FINE | Δ | 21 |
| | | | | | | | WIRE | | |
| TC-112 | LX435 | 50 | YES | ANION | −14 | 1 | Ag FINE | Δ | 28 |
| | | | | | | | WIRE | | |
| TC-113 | MD1480 | 25 | NO | ANION | 20 | 1 | Ag FINE | ◯ | 4 |
| | | | | | | | WIRE | | |
| TC-114 | P-1 | 20 | NO | NO | — | 1 | Ag FINE | ◯ | 4 |
| | AQ. | | | | | | WIRE | | |
| | SOLN | | | | | | | | |
| TC-115 | — | — | — | — | — | 1 | Ag FINE | X | 15 |
| | | | | | | | WIRE | | |

| | EVALUATION | | | | | | | | |
|---|---|---|---|---|---|---|---|---|---|
| | | | | AFTER FORCED DEGRADATION TEST | | | | | |
| TRANSPARENT | BEFORE FORCED | | | [80° C., 90% RH (5 DAYS)] | | | | | |
| ELECTRO- | DEGRADATION TEST | | | | SURFACE | | | | |
| CONDCTIVE | Ry | Ra | FILM | TRANS- | RESISTIVITY | Ry | Ra | FILM | |
| FILM NO. | [nm] | [nm] | STRENGTH | PARENCY | [Ω/□] | [nm] | [nm] | STRENGTH | REMARK |
| TC-108 | 25 | 4 | ⊚ | ⊚ | 18 | 29 | 6 | ⊚ | EXAMPLE |
| TC-109 | 23 | 4 | ⊚ | ◯ | 20 | 28 | 7 | ⊚ | EXAMPLE |
| TC-110 | 48 | 15 | Δ | Δ | 62 | 84 | 26 | X | COMPARATIVE |
| | | | | | | | | | EXAMPLE |
| TC-111 | 42 | 12 | Δ | X | 79 | 70 | 22 | X | COMPARATIVE |
| | | | | | | | | | EXAMPLE |
| TC-112 | 46 | 14 | Δ | X | 84 | 91 | 32 | X | COMPARATIVE |
| | | | | | | | | | EXAMPLE |
| TC-113 | 31 | 10 | Δ | Δ | 46 | 47 | 27 | X | COMPARATIVE |
| | | | | | | | | | EXAMPLE |
| TC-114 | 34 | 11 | Δ | Δ | 41 | 58 | 24 | X | COMPARATIVE |
| | | | | | | | | | EXAMPLE |
| TC-115 | 25 | 4 | ◯ | X | 49 | 34 | 14 | Δ | COMPARATIVE |
| | | | | | | | | | EXAMPLE |

FP3000: POLYSOL FP3000
MD1245: VYLONAL MD1245
RZ105: PLASCOAT RZ105
LX430: NYPOL LX430
MD1480: VYLONAL MD1480
1: POLYTHIOPHENE
MD1500: VYLONAL MD1500
RZ570: PLASCOAT RZ570
LX433C: NYPOL LX433C
2: POLYANILINE
MD2000: VYLONAL MD2000
RZ571: PLASCOAT RZ571
LX435: NYPOL LX435

It is understood from Tables 1-1 and 1-2 that, as compared with the transparent electroconductive films TC-110 to TC-115 of Comparative Examples, the transparent electroconductive films TC-101 to 109 of the Examples are more excellent in the smoothness, electroconductivity, luminous transmittance, and film strength, and less causative of degradation in the smoothness, electroconductivity, luminous transmittance, and film strength even under high-temperature, high-humidity environments, proving more excellent stability.

### Example 2

### Manufacturing of Organic EL Device

Each of the transparent electroconductive film bases manufactured in Example 1 was washed with ultra pure water, and cut into 30-mm square pieces so as to allow placement of 20-mm square tile-like transparent pattern at the center of each piece. Using each piece as an anode, an organic EL device was manufactured according to the procedures below. A hole transport layer and the layers stacked thereafter were formed by deposition. Organic EL devices OEL-201 to OEL-215 were manufactured using the transparent electroconductive films TC-101 to TC-115, respectively.

Necessary amounts of constitutive materials for composing the individual layers (Compounds 1-6 described below, CsF and Al) were respectively filled in evaporation crucibles of a deposition apparatus. The evaporation crucibles employed herein were made of molybdenum or tungsten suitable for electric resistance heating.

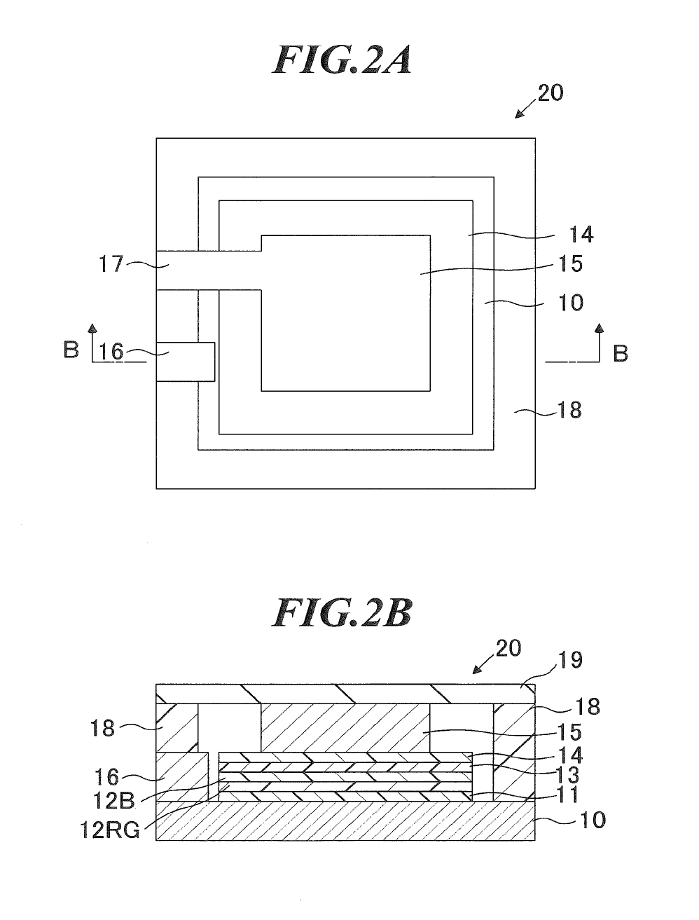

FIG. 2A is a top view of an exemplary organic EL device of the present invention, and FIG. 2B is a cross sectional view taken along line B-B in FIG. 2A.

First, using Compounds 1-6 described below, the hole transport layer 11, the organic luminescent layers 12RG and 12B, the hole blocking layer 13, and the electron transport layer 14 composing the organic EL layers were formed in a sequential manner.

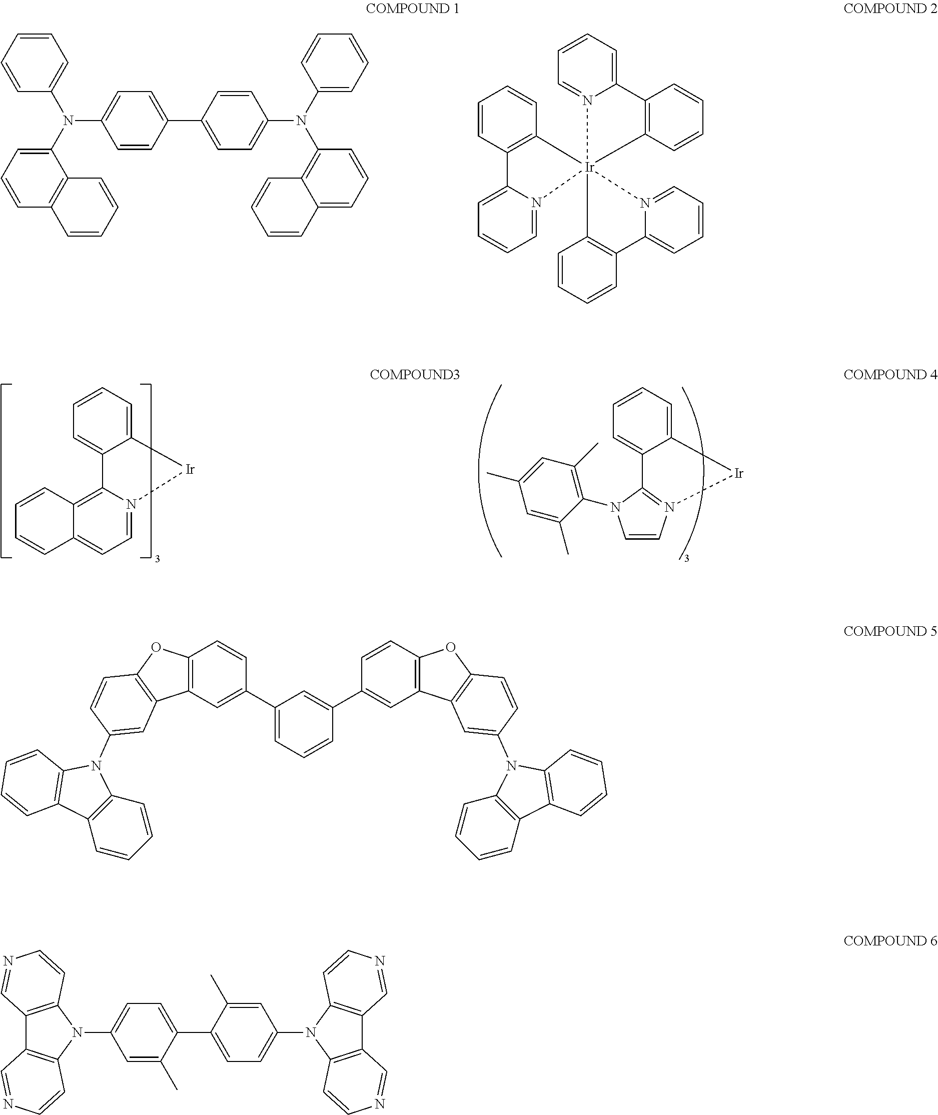

### <Formation of Hole Transport Layer>

The deposition apparatus was decompressed to 1×10⁻⁴ Pa, and the evaporation crucible containing Compound 1 was heated by current supply so as to proceed deposition at a deposition rate of 0.1 nm/second, to thereby form the hole transport layer 11 of 30 nm thick.

### <Formation of Organic Luminescent Layer>

Next, the individual luminescent layers were formed according procedures below.

On the thus-formed hole transport layer 11, Compound 2, Compound 3 and Compound 5 were co-deposited by deposition onto the same area with the hole transport layer 11, at a deposition rate of 0.1 nm/second, so as to adjust the content of Compound 2 to 13.0% by mass, the content of Compound 3 to 3.7% by mass, and the content of Compound 5 to 83.3% by mass, respectively, to thereby form a green-to-red phosphorescent organic luminescent layer 12RG of 10 nm thick, having a maximum emission wavelength of 622 nm.

Next, Compound 4 and Compound 5 were co-deposited by deposition onto the same area with the green-to-red phosphorescent organic luminescent layer, at a deposition rate of 0.1 nm/second, so as to adjust the content of Compound 4 to 10.0% by mass and the content of Compound 5 to 90.0% by mass, respectively, to thereby form a blue phosphorescent organic luminescent layer 12B of 15 nm thick, having a maximum emission wavelength of 471 nm.

### <Formation of Hole Blocking Layer>

Compound 6 was further deposited by deposition onto the same area with the thus-formed organic luminescent layers 12RG and 12B, to thereby form the hole blocking layer 13 of 5 nm thick.

### <Formation of Electron Transport Layer>

Next, CsF and Compound 6 were co-deposited by deposition onto the same area with the thus-formed hole blocking layer 13, so as to adjust the ratio of CsF to 10% of the film thickness, to thereby form the electron transport layer 14 of 45 nm thick.

### <Formation of Electrodes>

Al was deposited on the thus-formed electron transport layer 14 and an exposed portion of the transparent electroconductive film 10 to a thickness of 100 nm through a mask, by deposition at 5×10⁻⁴ Pa. Thus, a 15 mm×15 mm cathode 15 (second electrode) was formed on the electron transport layer 14; a cathode lead-out terminal 17 was formed on the electron transport layer 14 and on the transparent electroconductive film 10, extending from the cathode 15 to a circumference of the transparent electroconductive film 10; and an anode lead-out terminal 16 was formed on the circumference of the transparent electroconductive film 10. The transparent electroconductive film 10 connected to the anode lead-out terminal 16 serves as an anode (“first electrode” of Table 2). The cathode lead-out terminal 17 was insulated from the anode.

An adhesive 18 was then coated on a circumference of the top surface of the anode 15 around the above layers 11-15, but excluding a part where the cathode lead-out terminal 17 was formed, and a part where the anode lead-out terminal 16 was formed. Then, a flexible sealing component, composed of a polyethylene terephthalate base and a 300 nm-thick Al₂O₃ film formed thereon by deposition, was placed thereon. The stack was annealed so as to cure the adhesive 18 to thereby form a sealing film 19. An organic EL device 20 having an emission area of 15 mm×15 mm in size was thus manufactured.

<<Evaluation of Organic EL Device>>

The emission uniformity and service life of the thus-obtained organic EL devices were evaluated as below.

### (Emission Uniformity)

Emission uniformity was measured by allowing the organic EL device to emit light, under supply of DC voltage using a source measure unit Model 2400, from Keithley Instruments. Each of the organic EL devices OEL-201 to OEL-217 under emission of light at 1000 cd/m² was observed to determine uniformity of emission luminance, under a microscope at a ×50 magnification. The organic EL devices OEL-201 to OEL-217 were also annealed in an oven at 60% RH, 80° C. for 2 hours, then conditioned in an environment of 23±3° C., 55±3% RH for one hour or longer, and again observed similarly to determine the uniformity of emission luminance.

[symbol]

: (double circle) Perfect, with completely uniform emission;
◯: (single circle) no problem, with almost uniform emission;
Δ: (triangle) acceptable with a slight partial non-uniformity; and
x: (X) unacceptable with non-uniformity over the entire surface.

### (Service Life)

The thus-obtained organic EL devices were allowed to continuously emit light at an initial luminance of 5,000 cd/m² at a constant voltage, and the duration of time up to when the luminance was reduced by half was determined. The duration of time was expressed by a ratio relative to the duration of time shown by an organic EL device similarly manufactured but using an ITO anode. Results were evaluated according to the criteria below. The ratio is preferably 100% or larger, and more preferably 150% or larger.

[symbol]

: ≧150%;
◯: 100% or larger and smaller than 150%;
Δ: 80% or larger and smaller than 100%; and
x: <80%.
Results of evaluation are shown in Table 2 below.

TABLE 2

| | | EMISSION UNIFORMITY | | | |
|---|---|---|---|---|---|
| | FIRST | BEFORE | AFTER | | |
| ORGANIC EL | ELECTRODE | FORCED | FORCED | SERVICE | |
| DEVICE | (ANODE) | DEGRADATION | DEGRADATION | LIFE | REMARK |
| OEL-201 | TC-101 | ⊚ | ◯ | Δ | EXAMPLE |
| OEL-202 | TC-102 | ⊚ | ⊚ | ◯ | EXAMPLE |
| OEL-203 | TC-103 | ⊚ | ◯ | ⊚ | EXAMPLE |
| OEL-204 | TC-104 | ⊚ | ⊚ | ⊚ | EXAMPLE |
| OEL-205 | TC-105 | ⊚ | ⊚ | ⊚ | EXAMPLE |
| OEL-206 | TC-106 | ⊚ | ⊚ | ⊚ | EXAMPLE |
| OEL-207 | TC-107 | ◯ | ◯ | Δ | EXAMPLE |
| OEL-208 | TC-108 | ⊚ | ◯ | ⊚ | EXAMPLE |
| OEL-209 | TC-109 | ◯ | ◯ | Δ | EXAMPLE |
| OEL-210 | TC-110 | Δ | X | X | COMPARATIVE |
| | | | | | EXAMPLE |
| OEL-211 | TC-111 | Δ | X | X | COMPARATIVE |
| | | | | | EXAMPLE |
| OEL-212 | TC-112 | Δ | X | X | COMPARATIVE |
| | | | | | EXAMPLE |
| OEL-213 | TC-113 | ◯ | Δ | X | COMPARATIVE |
| | | | | | EXAMPLE |
| OEL-214 | TC-114 | ◯ | X | X | COMPARATIVE |
| | | | | | EXAMPLE |
| OEL-215 | TC-115 | ◯ | ◯ | Δ | COMPARATIVE |
| | | | | | EXAMPLE |

It is understood from Table 2 that, while the organic EL devices OEL-210 to OEL-215 of Comparative Examples show considerable degradation in the emission uniformity after being annealed at 80° C. for 30 minutes, the organic EL devices OEL-201 to OEL-209 of Examples are stable in the emission uniformity even after the heating, proving excellent durability.

As described in the above, according to the present invention, a transparent electroconductive film excellent in the transparency, electroconductivity, and strength of film, and less likely to degrade the transparency, electroconductivity, and strength of film even under high-temperature, high-humidity environments, may be obtained. By using the transparent electroconductive film as a transparent electrode, an organic EL device excellent in the emission uniformity, and less causative of degradation in the emission uniformity even under high-temperature, high-humidity environments, and having a long life of light emission, may be obtained.

What is claimed is:

1. A transparent electroconductive film comprising a transparent electroconductive layer containing:
an electroconductive polymer and
a self-dispersing polymer dispersible into aqueous solvent, wherein the self-dispersing polymer has a dissociable group, and has a glass transition point of 25° C. or higher and 80° C. or lower.

2. The transparent electroconductive film of claim 1, wherein the self-dispersing polymer has a glass transition point of 50° C. or higher and 70° C. or lower.

3. The transparent electroconductive film of claim 1, further comprising a transparent base having the transparent electroconductive layer thereon.

4. A transparent electroconductive film comprising
a patterned metal-containing electroconductive layer, and
a transparent electroconductive layer formed on the metal-containing electroconductive layer, wherein
the transparent electroconductive layer contains:
an electroconductive polymer and
a self-dispersing polymer dispersible into aqueous solvent, wherein the self-dispersing polymer has a dissociable group, and has a glass transition point of 25° C. or higher and 80° C. or lower.

5. The transparent electroconductive film of claim 2, wherein the self-dispersing polymer has a glass transition point of 50° C. or higher and 70° C. or lower.

6. The transparent electroconductive film of claim 4, wherein the patterned metal-containing electroconductive layer contains silver.

7. The transparent electroconductive film of claim 4, wherein the patterned metal-containing electroconductive layer has openings.

8. The transparent electroconductive film of claim 4, further comprising a transparent base having the metal-containing electroconductive layer thereon.

9. An organic electroluminescent device having a transparent electrode made of the transparent electroconductive film of claim 1.

10. An organic electroluminescent device having a transparent electrode made of the transparent electroconductive film of claim 2.

11. An organic electroluminescent device having a transparent electrode made of the transparent electroconductive film of claim 3.

12. An organic electroluminescent device having a transparent electrode made of the transparent electroconductive film of claim 4.

13. An organic electroluminescent device having a transparent electrode made of the transparent electroconductive film of claim 5.

14. An organic electroluminescent device having a transparent electrode made of the transparent electroconductive film of claim 6.

15. An organic electroluminescent device having a transparent electrode made of the transparent electroconductive film of claim 7.

16. An organic electroluminescent device having a transparent electrode made of the transparent electroconductive film of claim 8.
